(19) United States
(12) Patent Application Publication
(10) Pub. No.: US 2013/0120053 A1
(43) Pub. Date: May 16, 2013

(54) TOUCH PAD CAPACITIVE SENSOR CIRCUIT

(71) Applicants: Wangsheng MEI, Suzhou (CN); Yan Huang, Suzhou (CN); Wei Luo, Suzhou (CN); Yang Wang, Suzhou (CN); Jun Zhang, Suzhou (CN)

(72) Inventors: Wangsheng MEI, Suzhou (CN); Yan Huang, Suzhou (CN); Wei Luo, Suzhou (CN); Yang Wang, Suzhou (CN); Jun Zhang, Suzhou (CN)

(73) Assignee: FREESCALE SEMICONDUCTOR, INC., Austin, TX (US)

(21) Appl. No.: 13/604,646

(22) Filed: Sep. 6, 2012

(30) Foreign Application Priority Data
Nov. 16, 2011 (CN) 201110461367.X

(51) Int. Cl. H03K 17/96

(52) U.S. Cl. 327/517

(57) ABSTRACT

A touch pad capacitive sensor circuit has a signal generator that generates an oscillation signal having an oscillation frequency variable dependent on a capacitance in the sensor circuit. A switch switches a touch pad capacitive sensor of a capacitive touch pad connected to the signal generator in first and second cycles of the switch. A counter counts a first count of cycles of the oscillation signal when the sensor is connected to the signal generator in a first cycle of operation of the switch and a second count of cycles of the oscillation signal when the sensor is connected to the signal generator in a second cycle of operation. A detector detects when the first and second counts are below a low threshold number. The sensor circuit flags a valid user touch depending on an output of the detector.

### BACKGROUND OF THE INVENTION

The present invention relates to a touch pad capacitive sensor circuit and, more particularly, to a method of detecting a valid user touch of a touch pad capacitive sensor.

Touch sensors have become increasingly popular as more consumer and industrial designs include touch panels to provide simpler, more reliable user interfaces. Touch sensors have been implemented across a broad range of applications from, for example, mobile computing device touch screens to control panels on home appliances like microwave ovens. Typically, touch sensors operate on the principle that the touch pad has an inherent capacitive value (e.g., a value of parasitic capacitance from the pad sensor to ground). If a user touches the touch pad, this adds a second capacitance to ground in parallel with the pad's parasitic capacitance so when the user touches the capacitive pad sensor, it introduces the additional capacitance between the pad sensor, through the user's body, to ground. This results in a change in the net capacitance in the circuit (more specifically, an overall increase once the parallel capacitance values are added together), and recognition of this additional capacitance is exploited in a number of ways by existing techniques.

Provision of such sensors may offer significant benefits, such as the replacement of mechanical push-button switches. Sensors also may offer an improved user tactile experience, obviating the requirement for a user actually to depress a button. However, techniques commonplace in the art are not without their drawbacks. For instance, many touch pad sensors impose a relatively heavy electrical load, and relatively high power requirements. Some sensors are implemented in software, perhaps requiring the provision of a dedicated computing system. Even if a separate computing system is not necessary, implementation in software can impose a processing burden on the CPU. Thus, it would be advantageous to develop new techniques that might at least alleviate the aforementioned problems.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 is an electrical schematic diagram illustrating a touch pad capacitive sensor circuit according to an embodiment of the invention;

FIG. 2 is an electrical schematic diagram illustrating polling logic of a switch of the touch pad capacitive sensor circuit of FIG. 1;

FIG. 3 is an electrical schematic diagram illustrating in more detail a sub-circuit of a detector of the sensor circuit of FIG. 1;

FIG. 4 is a state transition diagram illustrating the transition of principal states of operation of the detector illustrated in FIG. 4;

FIG. 5 is a timing diagram illustrating operation of the touch pad capacitive sensor circuit of FIG. 1; and

FIG. 6 is an electrical schematic diagram illustrating in more detail a signal generator of the sensor circuit of FIG. 1.

### DETAILED DESCRIPTION OF THE INVENTION

In one embodiment of the invention, a touch pad capacitive sensor circuit includes a signal generator for generating an oscillation signal having an oscillation frequency that varies depending on a value of capacitance connected to the signal generator; a switch for switching a touch pad capacitive sensor of a capacitive touch pad in connection with the signal generator in a first cycle of operation of the switch and a second cycle of operation of the switch; a counter for counting a first count of cycles of the oscillation signal with the touch pad capacitive sensor connected to the signal generator in a first cycle of operation of the switch and a second count of cycles of the oscillation signal with the touch pad capacitive sensor connected to the signal generator in a second cycle of operation of the switch; and a detector configured to detect when the first count and the second count are below a low threshold number; wherein, in dependence of the detection, the touch pad capacitive sensor circuit is configured to flag a valid user touch of the touch pad capacitive sensor.

In another embodiment of the invention, there is provided a method of detecting a valid user touch of a touch pad capacitive sensor, the method comprising: providing a touch pad capacitive sensor circuit comprising: a signal generator; a switch; a counter; and a detector; the method comprising: generating, using the signal generator, an oscillation signal having an oscillation frequency which is variable dependent on a value of capacitance connected to the signal generator; switching, using the switch, a touch pad capacitive sensor of a capacitive touchpad in connection with the signal generator in a first cycle of operation of the switch and a second cycle of operation of the switch; counting, using the counter, a first count of cycles of the oscillation signal with the touch pad capacitive sensor connected to the signal generator in a first cycle of operation of the switch and a second count of cycles of the oscillation signal with the touch pad capacitive sensor connected to the signal generator in a second cycle of operation of the switch; detecting, using the detector, when the first count and the second count are below a low threshold number; and in dependence of the detection, flagging a valid user touch of the touch pad capacitive sensor.

Embodiments of the invention may provide significant technical benefits in comparison with conventional techniques. For instance, provision of a touch pad capacitive sensor circuit which makes at least two counts of cycles of an oscillation signal of a signal generator when a touch pad capacitive sensor is connected thereto, and detects when the two counts are below a low threshold number allows implementation of a de-bounce algorithm for the capacitive touchpad, thus leading to a reduction in instances of false detection which might otherwise occur because of, say, electrical noise in the sensor circuit. Additionally, provision of such a circuit may lead to reduced power consumption and the obvious benefits arising therefrom.

The invention may be implemented solely in hardware in contrast to a prevailing trend in the art for solutions based at least in part in software and the attendant burden imposed thereby on a processor. Further, implementation of a solution in hardware provides greater robustness and precision of detection of operation because a hardware-based approach is not reliant upon variations in CPU operating speed, temperature or voltages. Thus, the invention provides accurate and consistent measurement results. In further contrast with existing techniques, embodiments of the invention do not depend on any other on-chip peripherals, being a stand-alone module not requiring CPU intervention.

The terms “a” or “an,” as used herein, are defined as one or more than one. Also, the use of introductory phrases such as “at least one” and “one or more”, when used, in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to distinguish between elements and are not necessarily intended to indicate temporal or other prioritization of such elements.

Because the apparatus implementing the present invention is, for the most part, composed of electronic components known to those skilled in the art, these components will not be explained in any greater extent than that considered necessary for the understanding and appreciation of the underlying concepts of the present invention and in order not to obfuscate or distract from the teachings of the present invention.

Some of the embodiments may be implemented using a variety of different electronic circuit components, including digital and analog electronic circuit components. Of course, the description of the touch pad capacitive sensor circuit has been simplified for purposes of discussion, and it is just one of many different types of appropriate circuits that may be used in accordance with the invention. Those skilled in the art will recognize that the embodiment(s) described are merely illustrative and that alternative embodiments of the invention may be provided.

Further, alternative embodiments may include multiple instances of a particular operation, and the order of operations may be altered in various other embodiments.

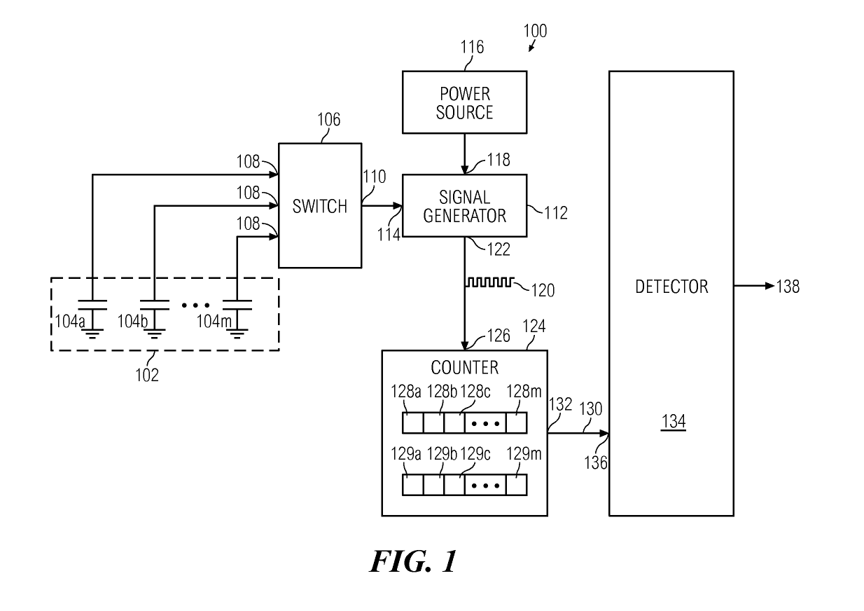

Referring now to FIG. 1, a touch pad capacitive sensor circuit 100 in accordance with an embodiment of the invention is shown. The sensor circuit 100 is connected to a touch pad capacitive sensor 102, which may or may not be provided as part of the touch pad capacitive sensor circuit 100; that is, the touch pad capacitive sensor 102 may be provided separately from the touch pad capacitive sensor circuit 100. The touch pad capacitive sensor 102 comprises individual touchpad sensors 104a, 104b, . . . , 104m, (collectively referred to as 104) represented by capacitors to indicate that they have a capacitance value. The individual touchpad sensors 104 may be, for example, touchpad sensors on a keypad such as one might find on a microwave oven control panel or, say, touchpad sensors for a touch screen display of a mobile computing device.

The touch pad capacitive sensor circuit 100 also comprises a switch 106 for receiving the connections from the touchpad sensors 104 on inputs 108. The switch 106 has an output 110 connected to a signal generator 112 at an input 114 thereof. The signal generator 112 is powered by a power source 116 connected at an input 118 of the signal generator 112.

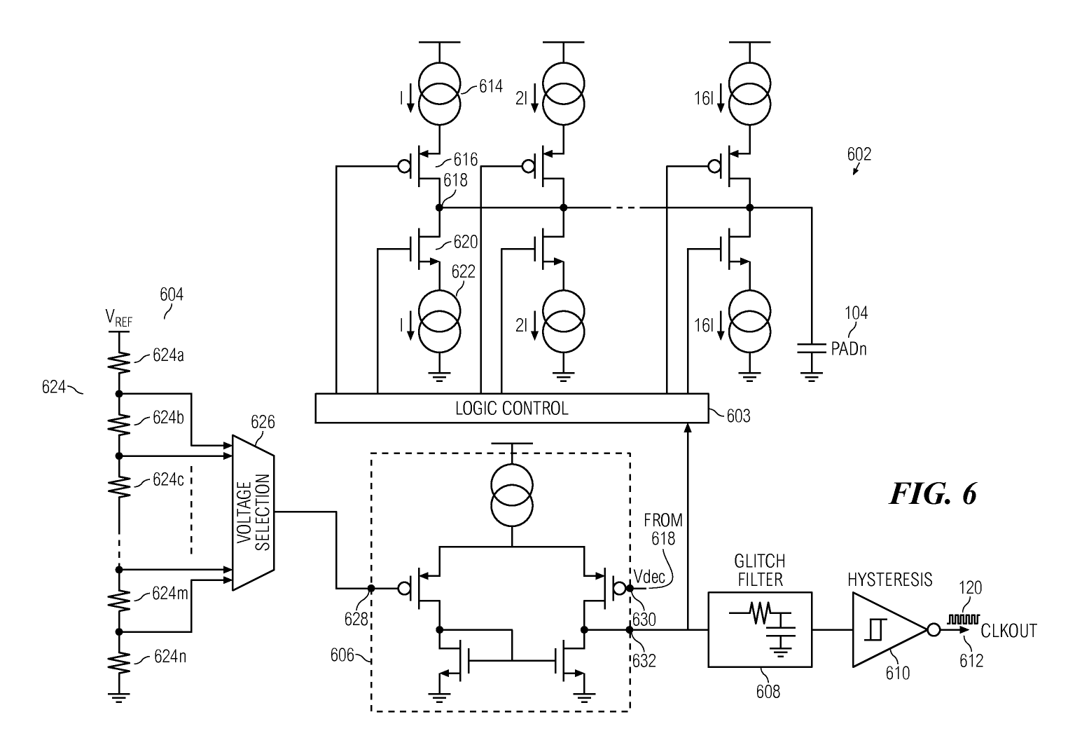

The signal generator 112 outputs an oscillation signal 120 on an output 122. The signal generator 112 may be an oscillator, such as a relaxation oscillator, just one implementation of which is described with reference to FIG. 6. The oscillation signal 120 is supplied to a counter 124 at an input 126 thereof. The counter 124 comprises buffers 128, 129 and outputs one or more output signals 130 at an output 132 to a detector 134, the detect 134 receiving the one or more output signals at an input 136. The detector 134 provides an output signal at an output 138.

In operation, the switch 106 operates a token-based (index-based) polling logic to poll, i.e. connect, in turn each of the capacitive pad sensors 104 in cycles of operation of the switch 106. This means that in the embodiment of FIG. 1, in a first cycle of operation, the switch 106 operates, in turn, to connect each capacitive pad sensor 104 with the signal generator 112. So, taking the example of capacitive pad sensor 104a as being the first sensor in the cycle of operation of the switch, the switch 106 connects the pad sensor 104a to the signal generator 112. Next, the switch 106 disconnects the capacitive pad sensor 104a from the signal generator 112 and connects the capacitive pad sensor 104b to the signal generator 112. Note that separate, sequentially-effected steps of disconnection of one capacitive pad sensor before connection of another one may not be necessary; depending on the precise configuration of the switch 106, the act of switching to the second capacitive pad sensor 104b may be sufficient to disconnect the capacitive pad sensor 104a from the signal generator 112. The switch 106 may be a mechanical switch or a solid-state device. The switch 106 continues in this duty cycle so that, in turn, each of the pad sensors 104 are polled by the switch 106 until the pad sensor 104m is connected to the signal generator 112. The switch 106 then repeats this cycle of operation, moving onto a next cycle of operation by disconnecting the pad sensor 104m from the signal generator 112 and connecting the sensor 104a to the signal generator 112 again, and so on. In at least one embodiment of the invention, the duty cycle of the switch 106 repeats itself until interrupted.

When a user touches a particular pad sensor 104, this connects another capacitance to the circuit, the capacitance of the user's body to ground, as described above. As a result of such a touch, the effective capacitance in the circuit is varied, more specifically is increased, by the amount of the capacitance of the user's body to ground. The operation of the signal generator 112 is such that, with the increased capacitance in the circuit, the oscillation frequency of the oscillation signal 120 is varied. In the embodiment of FIG. 1, the oscillation frequency of the oscillation signal 120 decreases with the increased capacitance in the circuit. This can be deduced from the equation F=I/2*C*V, where F is the frequency of oscillation of the oscillation signal 120, I is the charging current of a capacitive pad sensor, C is the capacitance connected in the circuit (whether the parasitic capacitance of the capacitive pad sensor 104, or the parasitic capacitance in parallel with the capacitance of the user's body to ground) and V is the capacitor charging voltage. If charging current and voltage are both held constant, it can be seen that with the increased capacitance connected in the circuit because of the user's touch of the pad sensor 104, the oscillation frequency of the oscillation signal 120 decreases.

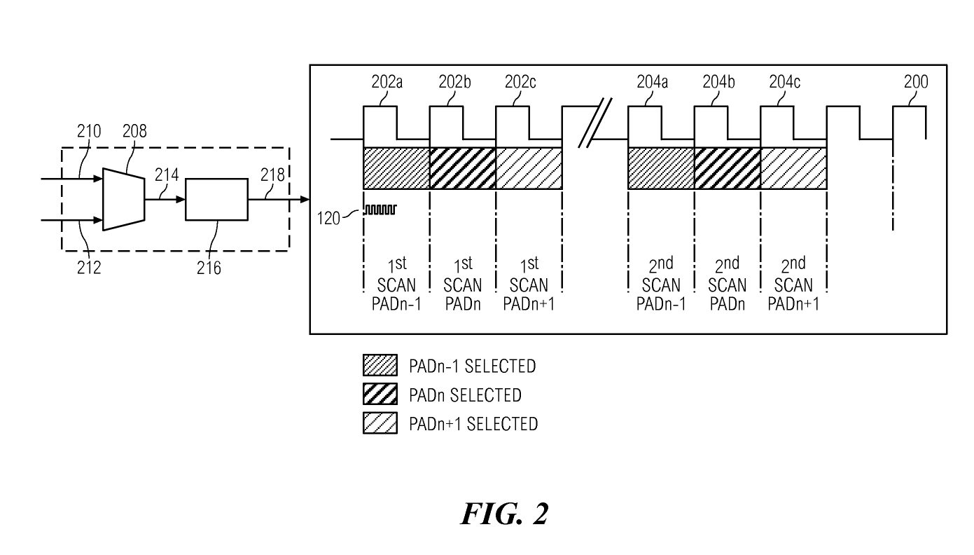

The number of cycles of the clock signal of the signal generator 112 is counted in a time window, discussed in more detail with reference to FIG. 2. In the current embodiment, the timing window is of fixed duration, so the lower the oscillation frequency, the lower the cycle count of the oscillation signal 120 in the timing window.

Continuing with the example of pad sensor 104a being the first pad sensor connected to the signal generator 112 by the switch 106, the counter 124 counts the number of cycles of the oscillation signal 120 in the fixed timing window and stores the count value in the buffer 128, specifically in buffer section 128a. The switch 106 then cycles through connection of each of the other pad sensors 104b-104m, counting the number of cycles of the oscillation signal 120 in each of the respective timing windows corresponding to the time in which the capacitive pad sensors 104b-104m are connected through the switch 106 to the signal generator 112. The count values for each of these counts are stored in the buffer 128, in respective buffer sections 128b-128m. The switch 106 then returns in the next cycle to connect (or re-connect) pad sensor 104a to the signal generator 112. In this cycle of operation, the counter 124 now counts the number of cycles of the oscillation signal 120 in the next fixed timing window corresponding to the time in which capacitive pad sensor 104a is connected to the signal generator 112, and also stores the value of the count in the buffer 129, specifically in buffer section 129a. As before, the switch 106 continues to cycle through its operational duty in turn connecting each of the pad sensors 104b-104m to the signal generator 112 and writing count values to buffer sections 129a-129m.

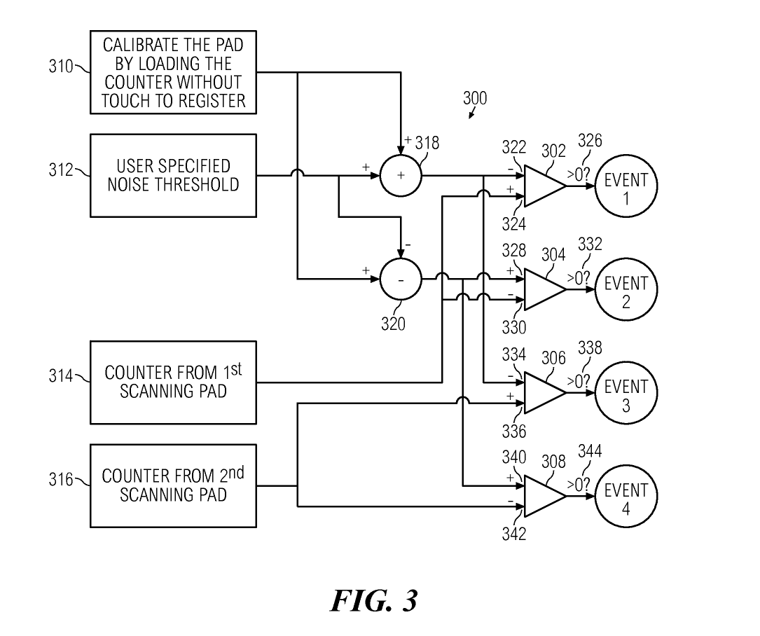

In the embodiment of FIG. 1, the count values stored in the buffer sections 128a, 128b are output as one or more counter output signals 130 to the detector 134 at the input 136 of the detector 134. The detector 134 compares each of the count values transmitted from buffer sections 128a, 129a with at least a low threshold number, described in more detail with reference to FIGS. 3 to 5, and, when both of the count values are below the low threshold number, the capacitive touch pad sensor circuit signals or flags at the output 138 the detection of a valid user touch of the capacitive pad sensor 104a. The flagging of the valid user touch may take the form of, for example, allowing the operation of the pad sensor. For example, if the pad sensor is a button on a control pad of a microwave oven, then the flagging of the valid user touch effects the functionality intended to be invoked by the activation of the button. The use of the low threshold number will be described in further detail below, but for the purposes of the discussion relating to FIG. 1, the low threshold number is derived from a value of capacitance in the circuit of a capacitive pad sensor, such as capacitive pad sensor 104a, with no touch by a user. If the number of counts is below the low threshold, then the capacitance connected in the circuit is higher than the capacitance value with no user touch, thus indicating a touch of the capacitive pad sensor 104a by the user. It is of course possible that the detection of a low count might be attributed to noise in the circuit, so embodiments of the invention implement a “de-bounce” algorithm by returning a valid user touch only when two (or more) counts are each detected to be below the low threshold number. In the embodiment of FIG. 1, the detector 134 compares two counts of cycles of the oscillation signal 120 in subsequent time frames for a particular capacitive pad sensor being connected to the signal generator 112. That is, the first count of cycles is a count of cycles of the oscillation signal 120 when a particular pad sensor 104 is connected to the signal generator 112, and the second count is a count of cycles of the oscillation signal 120 the next time the particular pad sensor 104 is connected to the signal generator 112 by the switch 106.

On the other hand, if the detector 134 does not return that both of the count values are below the low threshold, a valid user touch is not flagged.

As noted above, it may be advantageous for the two counts which are compared to the low threshold number to be counts for a particular pad sensor in subsequent cycles of the switch, in which case the second cycle of operation of the switch 106 is the next cycle of operation of the switch immediately following the first cycle of operation of the switch.

Although the preceding discussion is given in the context of just two cycles of operation of the switch 106, in the embodiment of FIG. 1 the switch 106 performs repeated, or iterative, cycles of operation. When a count has been made of the cycles of the oscillation signal 120 for a particular capacitive pad sensor 104 in two consecutive cycles of operation of the switch 106, count values from the buffer 129 are written to the buffer 128, and count values for the next (e.g., third or subsequent) cycle of operation may then be written to the buffer 129. Alternatively, values for the next cycle of operation of the switch 106 are written to the buffer 128 and compared with the values for the previous cycle stored in the buffer 129. As a further alternative, the count values may simply be transmitted on the fly to the detector 134 as the switch 106 cycles through the capacitive pad sensors 104 for the detector to perform the necessary operation thereon and the count values can be stored in buffers (not shown) in the detector 134.

It may be advantageous for the cycle time of the switch 106, the time for the switch first to connect a particular capacitive pad sensor such as pad sensor 104a, to cycle through all the remaining pad sensors 104b-104m and to return to reconnect sensor 104a to the signal generator 112, to be less than the typical human response required for activating a capacitive touch pad sensor (or to move from one touch pad sensor to another). A typical human response time is more than 100 mSec, whereas suitable cycle times implemented in embodiments of the invention are between 20 and 50 mSec. With such a configuration, the switch 106 cycles through connection of each of the pad sensors 104 more quickly than a human user can activate and then deactivate one of the pads. Thus, detection of two counts below the low threshold, particularly detection of two consecutive counts for a particular pad sensor 104 below the low threshold, is considered to be a safe indication of a valid user touch.

In embodiments of the invention, token-based polling logic may be implemented as illustrated in FIG. 2. FIG. 2 illustrates the selection of each capacitive pad sensor 104 in turn by the switch 106. Thus, FIG. 2 illustrates the cycles 200 of the switch 106 which, in this embodiment, is represented by a square wave having cycle portions 202a, 202b, 202c for each capacitive pad sensor in a first cycle of operation of the switch 106, and the generation of the oscillation signal 120 in each sub-cycle 202. In a second cycle of operation of the switch 106, the square wave has respective cycle portions 204a, 204b, 204c for each capacitive pad sensor for generation of the oscillation signal 120.

The counting of cycles 200 of the oscillation signal 120 may be effected in any of several ways. For example, the count can be effected upon detection of a rising edge or a falling edge (if the oscillation signal is a square wave as in FIG. 2), upon detection of a peak of the oscillation signal or even a trough to name just a few examples.

The present invention is not restricted to a regular, periodic waveform as illustrated in FIG. 2 for the generation of the oscillation signal. All that is required is that the number of maxima (minima or transitions between the two) of the oscillation signal 120 within a specified time frame varies depending on the value of the capacitance connected to the signal generator 112.

In the example of FIG. 2, the cycling of the switch 106 is controlled in accordance with a clock signal selector 208 arranged to select one of clock signals 210, 212. In embodiments of the invention, the touch pad capacitive sensor circuit is implemented in a microcontroller unit (MCU), system on chip (SOC) or the like. Such systems are typically provided with one or more clock signals and these may be advantageously used to control operation of the switch 106, rather than having to provide a dedicated control signal therefor. Where more than one clock signal is provided on the MCU, SOC or the like, these will typically be of different oscillation frequencies when compared with one another and, indeed, scaling of an existing clock signal may be necessary for operation in the touch pad capacitive sensor circuit illustrated. Such frequency scaling may be effected by outputting from the clock signal selector 208 on output 214 a selected clock signal that is input to a frequency scaler 216. A scaled clock signal is then output at output 218 of the frequency scaler 216 for controlling the cycling of switch 106.

Turning now to FIG. 3, a sub-circuit of the detector 134 is illustrated in more detail. The sub-circuit 300 includes comparators 302, 304, 306, 308. A calibration value 310 is derived by counting the number of cycles of the oscillation signal 120 for a particular touch pad capacitive sensor 104 when it is known that a user is not touching the pad sensor 104. A user-specified noise threshold 312 is also derived by counting the number of cycles of oscillation signal 124 a particular touch pad capacitive sensor 104 when it is known that a user is touching the pad sensor. The value of the count 314 from the counter 124 in the first cycle of operation of the switch is loaded from the buffer 128 and provided to the detector 134. The value 316 of the count from the counter 124 in the second cycle of operation of the switch is loaded from the buffer 129 and provided to the detector 134.

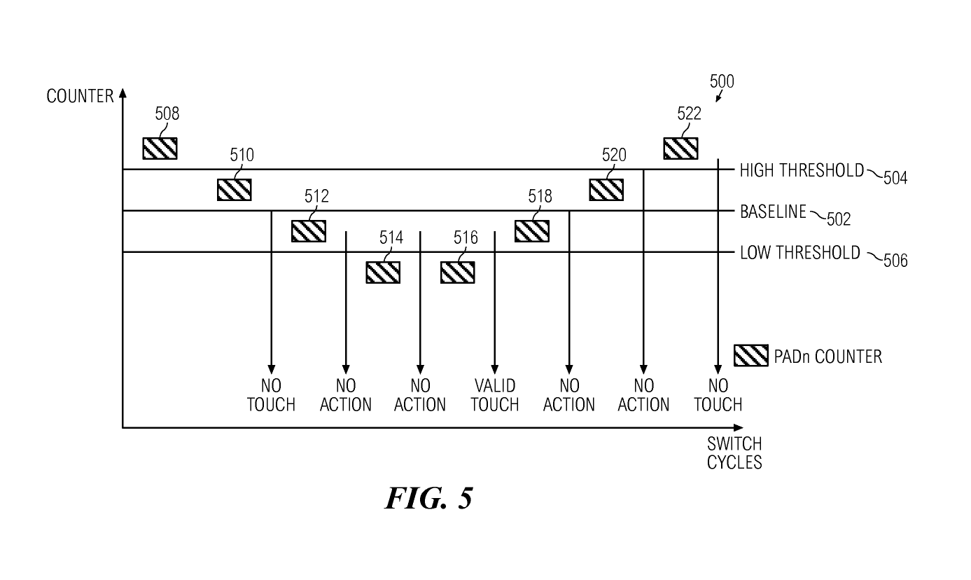

A high threshold number, described in greater detail below with reference to FIG. 5, and the low threshold number discussed above are derived through use of a summer 318 and a subtractor 320. The value 310 of the count of cycles of the oscillation signal 120 for a pad sensor 104 without the user's touch is provided as an input to the summer 318 where it is added with the value 312 of the user-specified noise threshold to create the high threshold value, which is provided as an output of the summer 318. The value 310 of the count of cycles of the oscillation signal for a pad sensor 104 without the user's touch is also provided as an input to the subtractor 320 where the value 312 of the user-specified noise threshold is subtracted from it to create the low threshold value. The output of the summer 318 is provided as an input 322 to the comparator 302. An input 324 of the comparator 302 is used to receive the count 314 of oscillations of the oscillation signal 120 in the first cycle of operation of the switch 106. The result of the comparison is provided as an output 326 of the comparator 302. The output of the subtractor 320 is provided as an input 328 to the comparator 304. An input 330 to the comparator 304 is used to receive the count 314 of oscillations of the oscillation signal 120 in the first cycle of operation of the switch 106. The result of the comparison is provided as an output 332 of the comparator 304. The output of the summer 318 is also provided as an input 334 to the comparator 306. The input 336 of the comparator 306 is used to receive the count 316 of oscillations of the oscillation signal 120 in the second cycle of operation of the switch 106. The result of the comparison is provided as an output 338 of the comparator 306. The output of the subtractor 320 is also provided as an input 340 to the comparator 308. An input 342 of the comparator 308 is used to receive the count 316 of oscillations of oscillation signal 120 in the second cycle of operation of the switch 106. The result of the comparison is provided as an output 344 of the comparator 308.

The comparator 304 detects whether the count 314 of oscillations of the oscillation signal 120 in the first cycle of operation is below the low threshold value; when the comparison of the input signals to the comparator 304 yields such a result, this is output on output 326 and such a detection is denoted an occurrence of “event 2”. Similarly, comparator 308 detects whether the count 316 of oscillations of oscillations signal 120 in the first cycle of operation is below the low threshold value. Such a detection is denoted an occurrence of “event 4”. Thus, detector 134 comprises a first comparator 304 for detecting when the first count 314 is below the low threshold number, the first comparator 304 having a first input 330 for receiving the first count from the counter and a second input 328 for receiving a user-specified noise value, the low threshold number being defined using the user-specified noise value. Additionally, detector 134 also comprises a second comparator 308 for detecting when the second count 316 is below the low threshold number, the second comparator 308 having a first input 342 for receiving the second count from the counter and a second input 340 for receiving a user-specified noise value, the low threshold number being defined using the user-specified noise value.

The detector 134 further detects when one of the first count and the second count is above a high threshold number, and if so, flags the detection as an occurrence of noise interference.

This functionality is effected using one or both of third and fourth comparators 302, 306. That is, detector 124 comprises a third comparator 302 for detecting when the first count 314 is above the high threshold number, the third comparator 302 having a first input 324 for receiving the first count 314 from the counter and a second input 322 for receiving a user-specified noise value, the high threshold number defined using the user-specified noise value. Such a detection is denoted an occurrence of “event 1”.

Additionally, the detector 124 comprises a fourth comparator 308 for detecting when the second count 316 is above the high threshold number, the fourth comparator 308 having a first input 342 for receiving the second count 316 from the counter and a second input 340 for receiving a user-specified noise value, the high threshold number being defined using the user-specified noise value. Such a detection is denoted an occurrence of “event 3”.

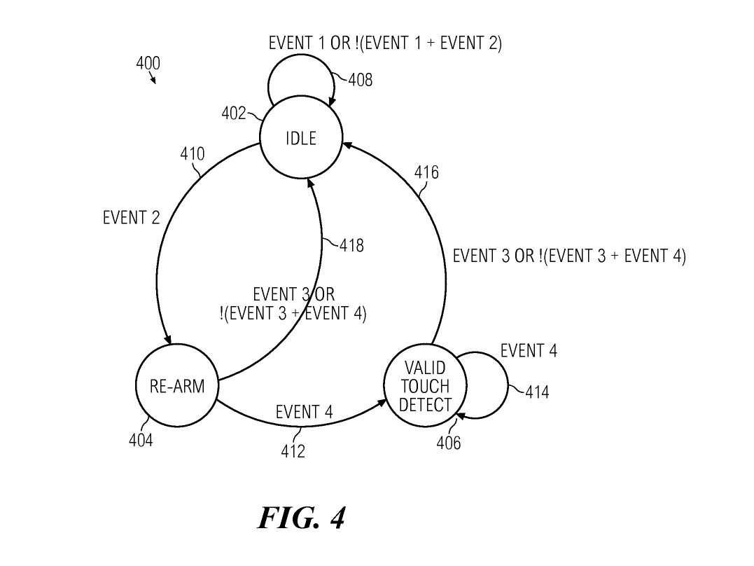

FIG. 4 is a state diagram illustrating the transition 400 of principal states of the sub-circuit 300 of FIG. 3. The sub-circuit 300 has a first, “idle” state 402, a second, “re-arm” state 404 and a third, “valid touch detect” state 406. The sub-circuit 300 is initialized in the first, idle state 402. The sub-circuit 300 holds 408 in first state 402 until detection of an “event 2”, the first count 314 being below the low threshold when the sub-circuit 300 makes a transition 410 to the second state 404. Thus, the sub-circuit 300 holds in first state 402 upon detection of an occurrence of event 1 or upon failure to detect either event 1 or event 2, denoted by “!(event 1+event 2)”, the occurrence of which will be more clearly illustrated in FIG. 5, described below.

When in the second, re-arm state 404, the sub-circuit 300 is primed by the detection of event 2, in anticipation of an occurrence of an event 4 but will not make a transition 412 to the third state 406 until detection of an event 4, the second count 316 being below the low threshold. Detection of an occurrence of event 4 following an occurrence of event 2 indicates a valid user touch of a capacitive pad sensor 104, at which point the detector 134 flags at output signal 138, illustrated in FIG. 1.

The sub-circuit 300 holds 414 in third state 406 while the detector 1345 detects that the two counts 314, 316 are below the low threshold and there is a continued user touch of the capacitive pad sensor 104. When the sub-circuit 300 detects an occurrence of an “event 3”, this means that the second count 316 is not below the threshold, and the valid user touch of the capacitive pad sensor 104 is no longer detected, the sub-circuit 300 makes a transition 416 back to the first, idle state 402. The sub-circuit 300 also makes the transition 416 back to the first state 402 when neither event 3 nor event 4 are detected, denoted by “!(event 3+event 4)”, the occurrence of which will be more clearly illustrated in FIG. 5 described below.

If, in the second state 404, the sub-circuit 300 does not detect an occurrence of an “event 4” this means that the second count 316 is above the threshold and the sub-circuit 300 makes a transition 418 back to the first state 402. Thus, the sub-circuit 300 returns from the second, re-arm state 404 to the first state 402 upon detection of an occurrence of an “event 3” or when neither an event 3 nor an event 4 are detected, denoted by “!(event 3+event 4)”.

As mentioned above, the touch pad capacitive sensor circuit maintains this operation, with the switch 106 cycling through connection of the individual pad sensors 104a-104m. Each time two counts are compared to determine whether they are below the low threshold. So for each cycle of operation, one of the counts is a count of the cycles of oscillation signal 120 in the current cycle of operation of the switch 106, and the other of the counts is a count of the cycles of oscillation signal 120 in a previous cycle of operation of the switch 106. Advantageously, the previous cycle may be the cycle immediately preceding the current cycle so that the detector 134 is comparing the counts in consecutive cycles of operation of the switch.

Thus, detector 124 is configured to hold in a first state 402 if the first count 314 is not below the low threshold number, to transition 410 to a second state 404 upon detection the first count 314 is below the low threshold number, and to transition 412 from the second state 404 to a third state 406 if the second count 316 is below the low threshold number, the third state 406 being indicative of a valid user touch of the touch pad capacitive sensor 104. Additionally, when the detector 124 is in the second state 404, it is configured to return to the first state 402 when the second count 316 is not below the low threshold number. Further, detector 124 is configured iteratively, in each cycle of subsequent cycles of operation of the switch 106, to detect whether two counts 314, 316 of cycles of the oscillation signal 120 of the signal generator 112 with the capacitive touch sensor connected 104 thereto are below the low threshold number, a first one of the two counts 314, 316 being a count of cycles of the oscillation signal 120 of the signal generator 112 in a preceding cycle of operation of the switch and a second one of the two counts being a count of cycles of the oscillation signal 120 of the signal generator 112 in a current cycle of operation of the switch 106 and, in dependence of the detection, for the capacitive touch sensor circuit 100 to flag a valid user touch of the capacitive touch sensor 104 for the preceding cycle of operation and the current cycle of operation.

The touch pad capacitive sensor circuit 100 is also configured, for when the detector 124 has transitioned to the third state 406, for the detector 124 to hold 414 in the third state 406 until the second one 316 of the two counts is not below the low threshold number. Further, the touch pad capacitive sensor circuit 100 is configured for the detector 124 to return to the first state 402 when the second one 316 of the two counts is not below the low threshold number.

FIG. 5 is a timing diagram illustrating operation of the touch pad capacitive sensor circuit of the embodiment of FIG. 1. The graph 500 illustrates the comparison of counter values with the threshold values derived by sub-circuit 300 illustrated in FIG. 3. As discussed above in relation to FIG. 3, a calibration value 310 is derived, corresponding to the count of cycles of the oscillation signal 120 for a particular capacitive pad sensor 104 when it is known that a user is not touching the pad sensor. This value is indicated in FIG. 5 by baseline 502. As also noted with relation to FIG. 3, a user-specified noise threshold value 312 is used to vary the calibrated value 310 to define a high threshold value and a low threshold value. The high threshold value is defined by adding the user-specified noise threshold value 312 to the calibrated value 310 using summer 318, with the output of the summer 318 being used as inputs to comparators 302, 306. As noted above, the high threshold value may be provided to flag an occurrence of noise interference. It may also be provided to filter out any instances where a human touching on the capacitive pad will result in an overall decrease in the total capacitance. In such cases, the counter will increase due to the human touch.

This high threshold facility may be reserved for future use. Depending on how the touch pad is coupled with a human body, if the capacitance becomes smaller when a finger touches it, it may also be possible to use the high threshold for touch detection.

A yet further possible application for use of the high threshold is when a second, and separate, fixed clock source is also used for counting. This is used in addition to the main signal generator 112 of FIG. 1 which, in this example, is used to define the width of the timing window in dependence of the amount of capacitance connected in the circuit. Then, when the capacitance in the circuit is increased, the width of the timing window is also increased. Therefore, the number of counts of the fixed clock signal in the wider timing window is also increased, perhaps above the high threshold, indicating the presence of a human touch on the pad.

The low threshold value is defined by subtracting the user-specified noise threshold value 312 from the calibrated value 310 using subtractor 320, with the output of the subtractor 320 being used as inputs to comparators 304, 308.

In FIG. 5, the high threshold is indicated by high threshold line 504 and the low threshold is indicated by low threshold line 506.

Count 508 is a “first count” 314 loaded from buffer 128 of counter 124, and supplied as an input to comparator 302 and to comparator 304. As indicated in FIG. 5, first count 508 is above low threshold value 506 (indeed, in this example, first count 508 is even above high threshold value 504). Thus, and referring to FIG. 4, detector 124 holds 408 in first state 402 because it has not detected an occurrence of “event 2”, which occurs when the first count is below the low threshold value 506. The next count 510 corresponds with second count 316, the count of cycles of oscillation signal 120 with the pad sensor 104 connected to the signal generator in the second cycle of operation of the switch 106. Again, this count is not below the low threshold 506 and, accordingly, detector 124 does not detect a valid user touch of the pad sensor 104. Referring to the state transition diagram of FIG. 4, sub-circuitry hundred would hold in the first state 402 for counts 508, 510.

In the next cycle of switch 106, count 510 is denoted first count 314, and count 512 is denoted the second count 316. A comparison of these count values with the low threshold 506 also yields that these are not below the low threshold, indeed, neither of these are below the low threshold 506, and as such detector 124 does not detect a valid user touch of the pad sensor 104. Referring again to FIG. 4, sub-circuit 300 of detector 124 holds 408 in first state 402.

In the following cycle of switch 106, count 512 is denoted first count 314 of FIG. 3 and new count 514 is denoted the second count 316 of FIG. 3. Again, detector 124 does not flag a valid user touch of the pad sensor 104 because both of these counts are not below low threshold 106, only one of them is. However, in the subsequent cycle of switch 106 the next count 516 is also below low threshold 506. Referring to FIG. 4, count 514 is now the “first count” 314, and sub-circuit 300 makes the transition 410 from first state 402 to second state 404. Additionally, count 516 is now the “second count” 316 is also below low threshold 506 and sub-circuit 300 makes the transition 412 from the second state 404 to third state 406 and detector 124 flags a valid user touch of the pad sensor 104 and outputs a signal accordingly on output 138.

Following the remainder of graph 500, it is seen that count 518 is above the low threshold 506 and, therefore, sub-circuit 300 makes the transition 416 from third state 406 to the first state 402. As counts 520, 522 are each above the low threshold 506, the sub-circuit 300 holds in the first state 402, and no flag of a valid user touch is made.

The capacitive touch pad sensor circuit described above has an average charging current of approximately 1 micro amp and a peak current consumption of less than 60 micro amps. Maximum response time of the circuit is around 16 ms.

FIG. 6 is a more detailed view of the power source 116 and signal generator 112 of FIG. 1. In this example, the signal generator 112 comprises a relaxation oscillator, the operation of which will now be described in more detail.

The circuit 600 comprises variable current source sub-circuit 602, logic control circuit 603, variable voltage source sub-circuit 604, comparator 606, glitch (R-C) filter 608 and hysteresis block 610, which outputs signal 120 (refer again to FIG. 1) on output 612.

Current source sub-circuit 602 has a first current branch I having first NMOS current source 614, P-type Metal Oxide Semiconductor (PMOS) 616, circuit node 618, NNMOS 620 and second NMOS current source 622. In the Example of FIG. 6, there are a total of 16 current branches I, 2I, . . . 16I, each of which is selectable through the switching of the PMOS and NMOS devices under control of the logic control 603 to power the capacitive pad sensor(s) 104 with varying current values. However, it may be preferable to define a “default” current branch, such as branch I. For instance, when branch I is selected, logic control module 603 simply switches off, i.e. switches to a non-conducting state, all of the PMOS and NMOS devices in the other branches.

Variable voltage source 604 comprises a resistor ladder 624 having resistors 624a, 624b, 624c . . . , 624m, 624n, which generates at least two reference voltages, hereafter termed “hi_ref” and “low_ref” output by voltage selection switch 626 (in this example a multiplexer) to the inverting input 630 of comparator 606. Selection of the different voltages hi_ref and low_ref may be effected through multiplexer 626 by control signals (not shown) from logic control circuit 603.

As noted above, resistor ladder 624 comprises n resistors, thereby meaning in theory that it would be possible to output multiple different voltage levels from voltage selection switch 626. However, in the embodiment of FIG. 6 only two different voltages (hi_ref and low_ref) are required. These two voltages are selected from the n resistor ladder voltages and multiplexer 626 need be only a two-stage multiplexer. Generation of the reference voltage in this manner provides at least two benefits in that: firstly, to choose the different delta voltage (delta voltage=hi_ref−low_ref) for the circuit operation, the lower delta voltage can be used in low-noise environments, and higher delta voltage can be used in higher-noise environments for improved robustness; and secondly, generation of two different voltages (hi_ref and low_ref) allows that one of them may be selected as the inverting input of comparator 606 at different times, depending upon specific requirements.

The non-inverting input 630 of comparator 606 is derived from node 618. When operation is initialized, the voltage at node 618 is at or near zero and this voltage level is supplied to input 630 of the comparator 606. When the selected voltage level from the resistor ladder 624 is selected by the multiplexer 626 as hi_ref to the non-inverting input 628 of the comparator 606, the output 632 of the comparator 606 is a logical LOW because the input is at or near zero or, at the very least, is at a level that is lower than the voltage level of hi_ref. The output 632 of comparator 606 is provided to the logic control module 603 which, in turn, switches on (i.e. to a conducting state) the PMOS device 616, and simultaneously switches off NMOS device 620 to ensure there is no leakage to ground through device 622. The voltage at node 618 begins to rise because of the charging of the capacitive pad sensor 104 which, of course, is fed as the non-inverting input 630 of comparator 606. When the voltage level at node 618 reaches the voltage of hi_ref supplied at inverting input 628, the output 632 of comparator 606 changes to logical HIGH. At this time, control logic module 603 controls multiplexer 626 so that its output is now changed to the low_ref value, which of course is then supplied to the inverting input 628 of comparator 606. Further, the logical HIGH on output 632 is supplied to control logic module 603 which in turn switches off PMOS device 616 and switches on NMOS device 620 for the capacitive pad sensor 104 to discharge to ground through device 622. As node 618 discharges, the voltage on falls on the non-inverting input 630 of comparator 606. When the voltage on the non-inverting input falls to the level of low_ref on inverting input 628, the output 632 of comparator 606 changes to logical LOW. The cycle repeats itself and a triangular (or substantially triangular) wave is generated on the non-inverting input 630, with a related square wave generated on the output 632. A stable and smooth clock signal 120 is generated through the RC glitch filter 608 and the hysteresis block 610 for output on output 612.

By now it should be appreciated that there has been provided a novel method of detecting a valid user touch of a touch pad capacitive sensor including a de-bounce algorithm in digital logic circuitry.

Although the invention is described herein with reference to specific embodiments, various modifications and changes can be made without departing from the scope of the present invention as set forth in the claims below. For example, although the exemplary embodiments described above are implemented at least in part in digital logic circuitry, this is not essential; for instance, the invention may be implemented using analog circuit components. Although the exemplary embodiments described above provide a solution implemented purely in hardware, that is not essential and the described functionality of the circuit may be implemented, at least in part, in a suitably-programmed computing device comprising one or more microprocessors configured to execute one or more routines loaded into a memory, such as a random access memory. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

1. A touch pad capacitive sensor circuit comprising:
a signal generator for generating an oscillation signal having an oscillation frequency which is variable dependent on a value of capacitance connected to the signal generator;
a switch for switching a touch pad capacitive sensor of a capacitive touchpad in connection with the signal generator in a first cycle of operation of the switch and a second cycle of operation of the switch;
a counter for counting a first count of cycles of the oscillation signal with the touch pad capacitive sensor connected to the signal generator in the first cycle of operation of the switch and a second count of cycles of the oscillation signal with the touch pad capacitive sensor connected to the signal generator in the second cycle of operation of the switch; and
a detector configured to detect when the first count and the second count are below a low threshold number; wherein,
in dependence of the detection, the touch pad capacitive sensor circuit is configured to flag a valid user touch of the touch pad capacitive sensor.

2. The touch pad capacitive sensor circuit of claim 1, wherein the second cycle of operation of the switch is a next cycle of operation of the switch following the first cycle of operation of the switch.

3. The touch pad capacitive sensor circuit of claim 1, wherein the detector holds in a first state if the first count is above the low threshold number, transitions to a second state upon detection that the first count is below the low threshold number, and transitions from the second state to a third state if the second count is below the low threshold number, wherein the third state indicates a valid user touch of the touch pad capacitive sensor.

4. The touch pad capacitive sensor circuit of claim 3, wherein when the detector is in the second state, the detector returns to the first state when the second count is above the low threshold number.

5. The touch pad capacitive sensor circuit of claim 3, configured iteratively, in each cycle of subsequent cycles of operation of the switch, to detect whether two counts of cycles of the oscillation signal of the signal generator with the capacitive touch sensor connected to the signal generator are below the low threshold number, a first one of the two counts being a count of cycles of the oscillation signal of the signal generator in a preceding cycle of operation of the switch and a second one of the two counts being a count of cycles of the oscillation signal of the signal generator in a current cycle of operation of the switch and, in dependence of the detection, for the capacitive touch sensor circuit to flag a valid user touch of the capacitive touch sensor for the preceding and current cycles of operation.

6. The touch pad capacitive sensor circuit of claim 5, wherein when the detector has transitioned to the third state, the detector holds in the third state until the second one of the two counts is above the low threshold number.

7. The touch pad capacitive sensor circuit of claim 6, wherein the detector returns to the first state when the second one of the two counts is above the low threshold number.

8. The touch pad capacitive sensor circuit of claim 1, wherein the detector comprises a first comparator for detecting when the first count is below the low threshold number, the first comparator having a first input for receiving the first count from the counter and a second input for receiving a count value derived from a user-specified noise value, the low threshold number being defined using the user-specified noise value.

9. The touch pad capacitive sensor circuit of claim 8, wherein the detector comprises a second comparator for detecting when the second count is below the low threshold number, the second comparator having a first input for receiving the second count from the counter and a second input for receiving the count value derived from the user-specified noise value, the low threshold number being defined using the user-specified noise value.

10. The touch pad capacitive sensor circuit of claim 1, wherein the detector further detects when one of the first count and the second count is above a high threshold number, and in dependence of the detection, flags the detection as an occurrence of noise interference.

11. The touch pad capacitive sensor circuit of claim 10, wherein the detector comprises a third comparator for detecting when the first count is above the high threshold number, the third comparator having a first input for receiving the first count from the counter and a second input for receiving a count value derived from a user-specified noise value, the high threshold number being defined using the user-specified noise value.

12. The touch pad capacitive sensor circuit of claim 11, wherein the detector comprises a fourth comparator for detecting when the second count is above the high threshold number, the fourth comparator having a first input for receiving the second count from the counter and a second input for receiving the count value derived from the user-specified noise value, the high threshold number being defined using the user-specified noise value.

13. The touch pad capacitive sensor circuit of claim 1, wherein the switch switches a plurality of touch pad capacitive sensors of the capacitive touch pad in connection with the signal generator in cycles of operation of the switch, and the touch pad capacitive sensor circuit further comprises a variable current source for supplying current to the signal generator and charging the touch pad capacitive sensors.

14. The touch pad capacitive sensor circuit of claim 1, wherein the switch switches a plurality of touch pad capacitive sensors of the capacitive touch pad in connection with the signal generator in cycles of operation of the switch, and the touch pad capacitive sensor circuit further comprises a variable voltage source for varying the charging voltage of the touch pad capacitive sensors.

15. A method of detecting a valid user touch of a touch pad capacitive sensor, wherein the capacitive sensor includes a capacitive sensor circuit comprising a signal generator, a switch, a counter, and a detector; the method comprising:
generating, using the signal generator, an oscillation signal having an oscillation frequency that varies depending on a capacitance value connected to the signal generator;
switching, using the switch, the touch pad capacitive sensor in connection with the signal generator in a first cycle of operation of the switch and a second cycle of operation of the switch;
counting, using the counter, a first count of cycles of the oscillation signal with the touch pad capacitive sensor is connected to the signal generator in a first cycle of operation of the switch and a second count of cycles of the oscillation signal with the touch pad capacitive sensor connected to the signal generator in a second cycle of operation of the switch;
detecting, using the detector, when the first count and the second count are below a low threshold number; and
in dependence of the detection, flagging a valid user touch of the touch pad capacitive sensor.

16. The method of claim 15, further comprising:
holding the detector in a first state if the first count is above the low threshold number; and
transitioning the detector to a second state upon detection that the first count is below the low threshold number.

17. The method of claim 16, further comprising, when the detector is in the second state, transitioning the detector to a third state if the second count is below the low threshold number, the third state being indicative of a valid user touch of the touch pad capacitive sensor.

18. The method of claim 17, further comprising, when the detector is in the second state, returning the detector to the first state when the second count is above the low threshold number.

19. The method of claim 18, further comprising iteratively, in each cycle of subsequent cycles of operation of the switch, detecting whether two counts of cycles of the oscillation signal are below the low threshold number, a first one of the two counts being a count of cycles of the oscillation signal of the signal generator in a preceding cycle of operation of the switch and a second one of the two counts being a count of cycles of the oscillation signal of the signal generator in a current cycle of operation of the switch and, in dependence of the detection, flagging a valid user touch of the capacitive touch sensor for the preceding cycle of operation and the current cycle of operation.

20. The method of claim 19, further comprising, when the detector is in the third state, holding the detector in the third state until a second one of the two counts is above the low threshold number.
